(19) United States
(12) Patent Application Publication
(10) Pub. No.: US 2025/0079168 A1
(43) Pub. Date: Mar. 6, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Ta-Wei Chiu, Changhua County (TW); Ping-Hung Chiang, Tainan City (TW); Shin-Hung Li, Nantou County (TW); Shan-Shi Huang, Hsinchu City (TW)

(73) Assignee: UNITED MICROELECTRONICS CORP., Hsin-Chu City (TW)

(21) Appl. No.: 18/378,666

(22) Filed: Oct. 11, 2023

(30) Foreign Application Priority Data
Sep. 4, 2023 (TW) 112133503

(51) Int. Cl. H01L 21/02; H01L 21/265; H01L 21/8234; H01L 29/66

(52) U.S. Cl. CPC H01L 21/02554; H01L 21/02472; H01L 21/26506; H10D 64/021; H10D 84/0144; H10D 84/0147; H10D 84/038

(57) ABSTRACT

A semiconductor device includes a substrate, a first oxide layer and a second oxide layer. The substrate has a first region and a second region. The first oxide layer is disposed on the first region. The first oxide layer includes a first thermal oxide layer and a first deposited oxide layer, and a portion of the first thermal oxide layer is formed by a pad oxide layer. The second oxide layer is disposed on the second region. The second oxide layer includes a second thermal oxide layer and a second deposited oxide layer.

### BACKGROUND OF THE INVENTION

### 1. Field of the Invention

The present disclosure relates to the field of semiconductor devices, and more particularly, to a semiconductor device and a method for fabricating the same.

### 2. Description of the Prior Art

In advanced semiconductor technology, semiconductor devices having different operation voltages may be integrally formed in a same chip for reducing production cost, enhancing performance and also achieving a lower power consumption to meet the needs of various products.

However, semiconductor devices having different operation voltages usually require gate dielectric layers with different thicknesses. For example, a semiconductor device having a higher operation voltage requires a thicker gate dielectric layer to sustain the higher operation voltage. For fabricating the gate dielectric layers with different thicknesses, some process problems may arise. For example, additional processes may be required, which may enhance the complexity and the cost of the process. Therefore, there still needs an improved semiconductor device and fabricating method thereof that can successfully integrate semiconductor devices with different operation voltages in the same chip in the field.

### SUMMARY OF THE INVENTION

According to one aspect of the present disclosure, a semiconductor device includes a substrate, a first oxide layer and a second oxide layer. The substrate has a first region and a second region. The first oxide layer is disposed on the first region. The first oxide layer includes a first thermal oxide layer and a first deposited oxide layer, and a portion of the first thermal oxide layer is formed by a pad oxide layer. The second oxide layer is disposed on the second region. The second oxide layer includes a second thermal oxide layer and a second deposited oxide layer.

According to another aspect of the present disclosure, a method for fabricating a semiconductor device is disclosed. The method includes steps as follows. A substrate having a first region and a second region is provided. A first pad oxide layer is formed on the first region. A thermal oxidation process is performed to respectively form a first thermal oxide layer and a second thermal oxide layer on the first region and the second region, in which a portion of the first thermal oxide layer is formed by the first pad oxide layer. A deposition process is performed to form a first deposited oxide layer on the first thermal oxide layer in the first region and a second deposited oxide layer on the second thermal oxide layer in the second region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7, FIG. 8, FIG. 9 and FIG. 10 are schematic cross-sectional views showing steps of a method for fabricating a semiconductor device according to one embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

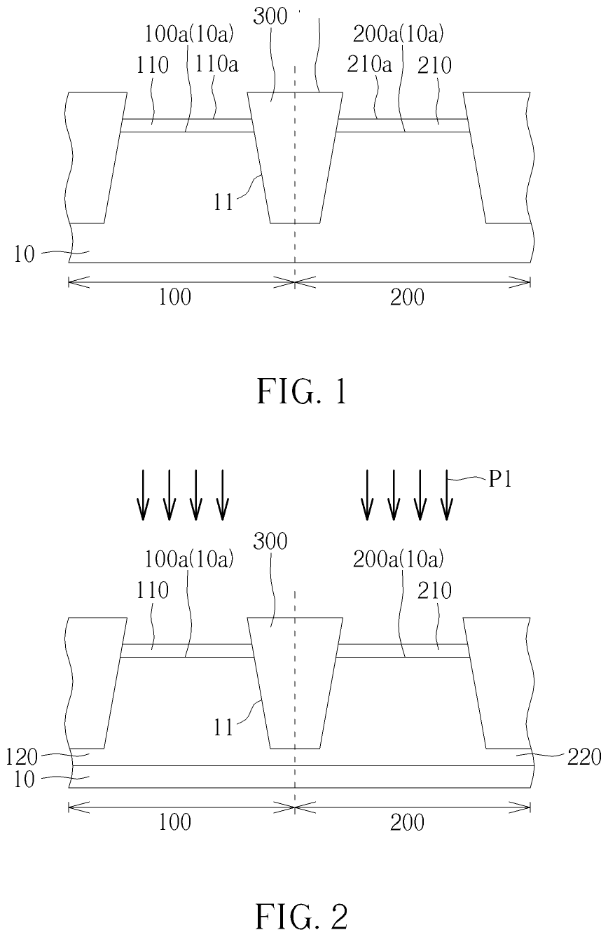

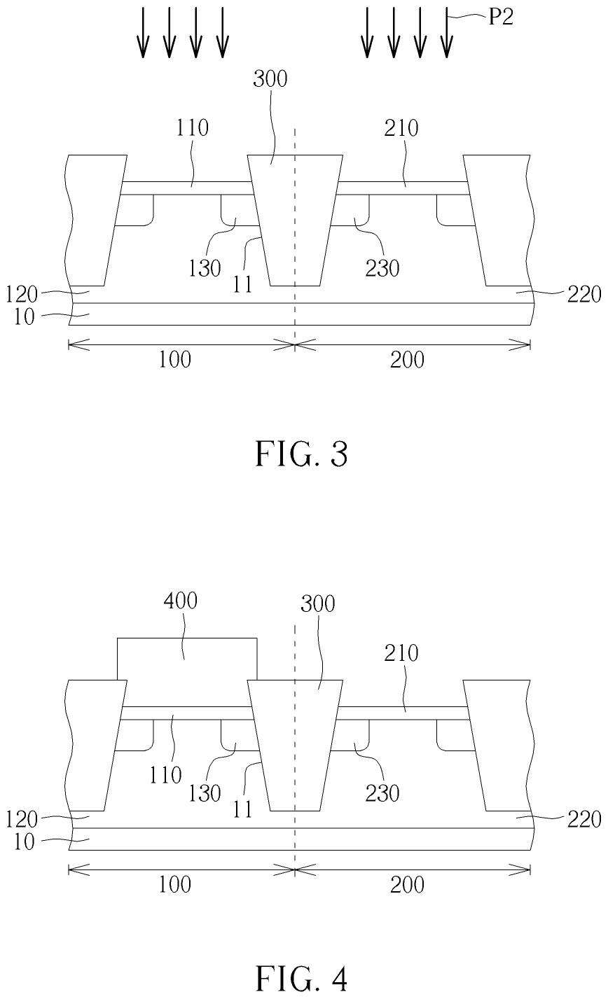

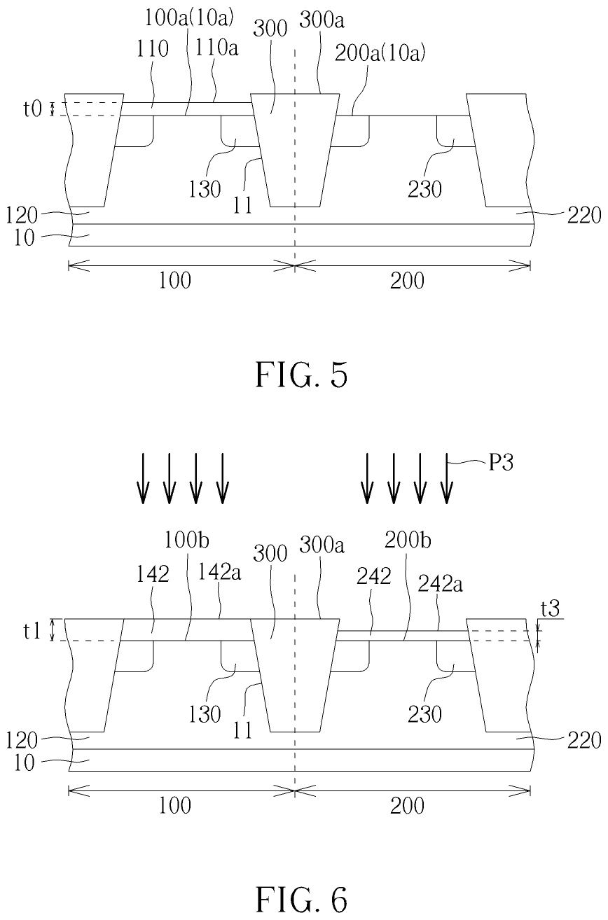

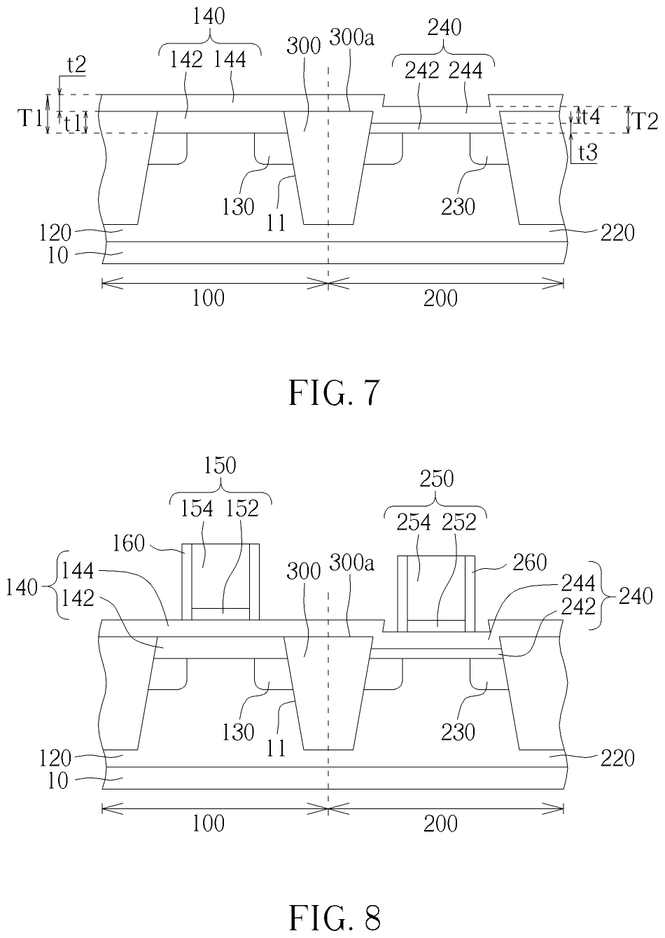

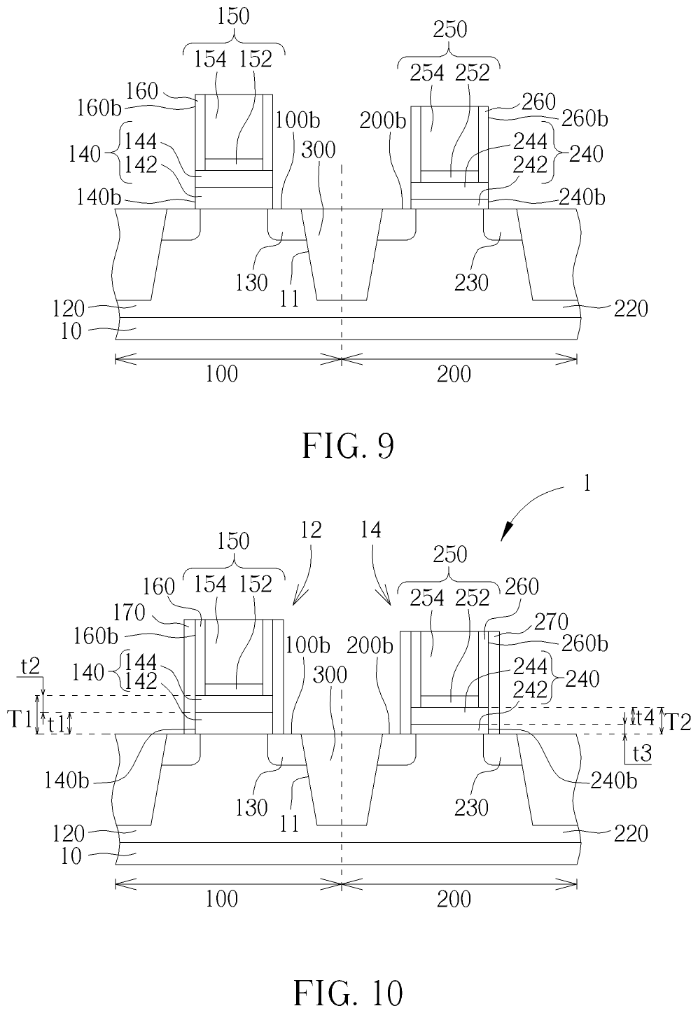

Please refer to FIG. 1 to FIG. 10, which are schematic cross-sectional views showing steps of a method for fabricating a semiconductor device according to one embodiment of the present disclosure. As shown in FIG. 1, a substrate 10 is provided first. The substrate 10 may be a silicon substrate, an epitaxial silicon substrate, a silicon carbide substrate or a silicon on insulator (SOI) substrate. Next, an insulating structure 300 is formed in substrate 10 to define a first region 100 and a second region 200. The insulating structure 300, for example, may be a shallow trench isolation (STI). A material of the insulating structure 300 may include a dielectric material, such as silicon dioxide. A portion of the insulating structure 300 is in the substrate 10 (that is, embedded in the substrate 10), and the other portion of the insulating structure 300 protrudes from a top surface 10a (such as a top surface 100a of the substrate 10 in the first region 100 and a top surface 200a of the substrate 10 in the second region 200) of the substrate 10. That is, a top surface 300a of the insulating structure 300 is higher than the top surface 10a of the substrate 10. Furthermore, a first pad oxide layer 110 is formed on the first region 100, and a second pad oxide layer 210 is formed on the second region 200. The first pad oxide layer 110 and the second pad oxide layer 210 may be configured to protect the substrate 10 in the subsequent first ion implantation process P1 (see FIG. 2).

The insulating structure 300, the first pad oxide layer 110 and the second pad oxide layer 210 may be formed simultaneously. For example, a pad oxide material layer (not shown) and a hard mask material layer (not shown) may be formed sequentially on the top surface 10a of the substrate 10. A material of the pad oxide material layer may include an oxide, such as silicon dioxide, and a material of the hard mask material layer may include a nitride, such as silicon nitride, but not limited thereto. Next, the pad oxide material layer and the hard mask material layer may be patterned by processes, such as photolithography process and etching process, and a recess 11 is formed in the substrate 10. Next, a dielectric material is filled in the recess 11 by a deposition process, and then a planarization process such as a chemical mechanical polishing (CMP) process is performed, so that a top surface of the dielectric material (i.e., the top surface 300a of the subsequently formed insulating structure 300) is aligned with a top surface (not shown) of the patterned hard mask material layer. At last, the patterned hard mask material layer is removed by an etching process to complete the fabrication of the insulating structure 300, and the remaining portions of the patterned pad oxide material layer are the first pad oxide layer 110 and the second pad oxide layer 210. As shown in FIG. 1, the top surface 300a of the insulating structure 300 may be higher than the top surface 110a of the first pad oxide layer 110 and the top surface 210a of the second pad oxide layer 210.

The first region 100 and the second region 200 may be configured to disposed devices with different operation voltages. Herein, the first region 100 and the second region 200 are adjacent to each other, which is for the convenience of drawing and explanation, and the present disclosure is not limited thereto. The positions of the first region 100 and the second region 200 on the substrate 10 may be adjusted according to design requirements.

Next, as shown in FIG. 2, a first ion implantation process P1 is performed to form a first well region 120 and a second well region 220 in the first region 100 and the second region 200 of the substrate 10, respectively. The first well region 120 and the second well region 220 may have the same or different conductivity types. For example, the first well region 120 and the second well region 220 may be independently an N-type well region or a P-type well region, and may have the same or different types of dopant, doping concentrations and doping depths, depending on the design of the device. For example, the first region 100 and the second region 200 may be configured to dispose a device with an operation voltage of 10 V and a device with an operation voltage of 8 V, respectively. Therefore, the doping concentration and doping depth of the first well region 120 and the second well region 220 may be adjusted according to the operation voltage. By disposing the first pad oxide layer 110 and the second pad oxide layer 210 on the top surface 100a of the substrate 10 in the first region 100 and the top surface 200a of the substrate 10 in the second region 200, the probability of tunneling effect during the first ion implantation process P1 can be reduced, which is beneficial to control the depths of the first well region 120 and the second well region 220, and improve the yield of the semiconductor device 1 (see FIG. 10) subsequently formed.

Next, as shown in FIG. 3, a second ion implantation process P2 is performed to form two first light doped drains (LDDs) 130 in the first well region 120, and to form two second light doped drains 230 in the second well region 220. The two first light doped drains 130 are separated from each other and located at two opposite sides of the first well region 120, and the two second light doped drains 230 are separated from each other and located at two opposite sides of the second well region 220.

Next, as shown in FIG. 4, a patterned mask 400 is formed on the first region 100. The patterned mask 400 completely covers the first pad oxide layer 110 and exposes the second pad oxide layer 210. The patterned mask 400 may be, for example, a patterned photoresist layer, but not limited thereto.

Next, as shown in FIG. 5, the second pad oxide layer 210 is completely removed to expose the top surface 200a of the substrate 10 in the second region 200. Next, the patterned mask 400 is removed to expose the top surface 110a of the first pad oxide layer 110. In addition, one or more cleaning processes are performed, so that the top surface 300a of the insulating structure 300 is slightly higher than or substantially aligned with the top surface 110a of the first pad oxide layer 110. As shown in FIG. 5, the first pad oxide layer 110 has a thickness to.

Next, as shown in FIG. 6, a thermal oxidation process P3 is performed to form a first thermal oxide layer 142 and a second thermal oxide layer 242 on the first region 100 and the second region 200, respectively, wherein a portion of the first thermal oxide layer 142 is formed by the first pad oxide layer 110. For example, the thermal oxidation process P3 may be performed in an oxygen-containing environment. The oxygen-containing environment may be achieved by introducing oxygen or oxygen-containing gas (such as water vapor) into the process chamber of the thermal oxidation process P3. According to an embodiment of the present disclosure, the thermal oxidation process P3 may include in-situ steam generation (ISSG) oxidation process, wet furnace oxidation process, or dry furnace oxidation process, but not limited thereto.

In the thermal oxidation process P3, the surface layer (not labeled) of the substrate 10 in the first region 100 and the second region 200 is oxidized. The oxidized portion of the surface layer of the substrate 10 in the first region 100 and the first pad oxide layer 110 together form the first thermal oxide layer 142, and the oxidized portion of the surface layer of the substrate 10 in the second region 200 forms the second thermal oxide layer 242. Therefore, after performing the thermal oxidation process P3, the top surface 100b of the substrate 10 in the first region 100 is slightly lower than the top surface 100a before performing the thermal oxidation process P3, and the top surface 200b of the substrate 10 in the second region 200 is slightly lower than the top surface 200a before performing the thermal oxidation process P3. In addition, since the oxygen atom in the oxygen-containing gas enter into the substrate 10 and combine with the silicon in the substrate 10, after performing the thermal oxidation process P3, the top surface 142a of the first thermal oxide layer 142 in the first region 100 is slightly higher than or substantially aligned with the top surface 110a of the first pad oxide layer 110 before performing the thermal oxidation process P3, and the top surface 242a of the second thermal oxide layer 242 in the second region 200 is slightly higher than or substantially aligned with the top surface 200a of the substrate 10 in the second region 200 before performing the thermal oxidation process P3.

As shown in FIG. 6, the first thermal oxide layer 142 has a thickness t1, the second thermal oxide layer 242 has a thickness t3, and the thickness t1 of the first thermal oxide layer 142 is greater than the thickness t3 of the second thermal oxide layer 242. According to an embodiment of the present disclosure, a ratio of the thickness t1 of the first thermal oxide layer 142 to the thickness t3 of the second thermal oxide layer 242 (t1/t3) may be 1.3 to 1.4, such as 1.35, but not limited thereto. The thickness t1, the thickness t3 and the ratio of the thickness t1 to the thickness t3 may be controlled by adjusting the thickness to of the first pad oxide layer 110 and parameters of the thermal oxidation process P3 according to actual needs. Furthermore, in the thermal oxidation process P3, since the first region 100 is disposed with the first pad oxide layer 110, the oxidation rate of the surface layer of the substrate 10 in the first region 100 is less than the oxidation rate of the surface layer of the substrate 10 in the second region 200. Therefore, the increased thickness of the first thermal oxide layer 142 relative to the first pad oxide layer 110 (i.e., t1-t0) is less than the thickness t3 of the second thermal oxide layer 242.

Next, as shown in FIG. 7, a deposition process is performed to form a first deposited oxide layer 144 on the first thermal oxide layer 142 in the first region 100 and a second deposited oxide layer 244 on the second thermal oxide layer 242 in the second region 200. The first deposited oxide layer 144 and the second deposited oxide layer 244 may be formed at the same time. Therefore, the thickness t2 of the first deposited oxide layer 144 may be equal to the thickness t4 of the second deposited oxide layer 244. The deposition process may be, for example, an atomic layer deposition (ALD) process.

As shown in FIG. 7, the thickness t1 of the first thermal oxide layer 142 may be greater than the thickness t2 of the first deposited oxide layer 144. In FIG. 7, the thickness t3 of the second thermal oxide layer 242 is less than the thickness t4 of the second deposited oxide layer 244, but not limited thereto. The thickness t3 of the second thermal oxide layer 242 may be greater than the thickness t4 of the second deposited oxide layer 244. According to an embodiment of the present disclosure, a ratio of the thickness t1 of the first thermal oxide layer 142 to the thickness t2 of the first deposited oxide layer 144 (t1/t2) may be 2.3 to 3.1, such as 2.7. A ratio of the thickness t3 of the second thermal oxide layer 242 to the thickness t4 of the second deposited oxide layer 244 (t3/t4) may be 1.6 to 2.4, such as 2. However, the present disclosure is not limited thereto, the parameters of the atomic layer deposition process may be adjusted according to actual needs, such that the thicknesses T1 and T2 required by the first oxide layer 140 and the second oxide layer 240 may be adjusted by the differences, such as in density, dielectric constant, physical properties, between the oxides formed by the atomic layer deposition process and the thermal oxidation process P3.

As shown in FIG. 7, in the first region 100, the first thermal oxide layer 142 and the first deposited oxide layer 144 together form the first oxide layer 140. In the second region 200, the second thermal oxide layer 242 and the second deposited oxide layer 244 together form the second oxide layer 240. The sum of the thickness t2 of the first deposited oxide layer 144 and the thickness t1 of the first thermal oxide layer 142 (t2+t1) is greater than the sum of the thickness t4 of the second deposited oxide layer 244 and the thickness t3 of the second thermal oxide layer 242 (t4+t3). In other words, the thickness T1 of the first oxide layer 140 is greater than the thickness T2 of the second oxide layer 240. According to an embodiment of the present disclosure, a ratio of the thickness T1 of the first oxide layer 140 to the thickness T2 of the second oxide layer 240 (T1/T2) may be 1.20 to 1.28, such as 1.24, but not limited thereto. The thicknesses t1, t2, t3 and t4 may be controlled by actual needs, so as to control the ratio of the thickness T1 to the thickness T2.

Next, as shown in FIG. 8, a first gate 150 is formed on the first oxide layer 140, and a second gate 250 is formed on the second oxide layer 240. The first gate 150 includes a first high dielectric constant (high-k) material layer 152 and a first gate material layer 154, and the first gate material layer 154 is disposed on the first high-k material layer 152. The second gate 250 includes a second high-k material layer 252 and a second gate material layer 254, and the second gate material layer 254 is disposed on the second high-k material layer 252. The first gate 150 and the second gate 250 may be formed at the same time. For example, a high-k material layer (not shown) and a gate material layer (not shown) may be sequentially deposited on the substrate 10, and then a portion of the gate material layer and a portion of the high-k material layer may be removed by a patterning process, so as to form the first gate material layer 154, the second gate material layer 254, the first high-k material layer 152 and the second high-k material layer 252 to complete the fabrication of the first gate 150 and the second gate 250.

Materials of the first gate material layer 154 and the second gate material layer 254 may include non-metallic conductive materials, such as polysilicon. The first high-k material layer 152 and the second high-k material layer 252 may include dielectric materials with a dielectric constant greater than 4, such as hafnium oxide (HfO₂), hafnium silicon oxide (HfSiO₄) or hafnium silicon oxynitride (HfSiON). In other embodiments, the first gate 150 may optionally include a first interface layer (IL, not shown) disposed between the first high-k material layer 152 and the first oxide layer 140, and the second gate 250 may optionally include a second interface layer (not shown) disposed between the second high-k material layer 252 and the second oxide layer 240. Materials of the first interface layer and the second interface layer may include oxides, nitrides or oxynitrides.

Please continue to refer to FIG. 8. Next, a first spacer 160 surrounding the first gate 150 and disposed on the first oxide layer 140 and a second spacer 260 surrounding the second gate 250 and disposed on the second oxide layer 240 are formed by processes, such as deposition process, lithography process and etching process. Materials of the first spacer 160 and the second spacer 260 may independently include oxides and/or nitrides, such as silicon dioxide, silicon nitride, silicon oxynitride or silicon carbonitride.

Next, as shown in FIG. 9, a portion of the first oxide layer 140 and a portion of the second oxide layer 240 may be removed by an etching process, so that an outer side surface 160b of the first spacer 160 is aligned with a side surface 140b of the first oxide layer 140, and an outer side surface 260b of the second spacer 260 is aligned with a side surface 240b of the second oxide layer 240, and the top surface 100b of the substrate 10 in the first region 100 and the top surface 200b of the substrate 10 in the second region 200 are exposed.

Next, as shown in FIG. 10, a third spacer 170 surrounding the first spacer 160 and the first oxide layer 140 and a fourth spacer 270 surrounding the second spacer 260 and the second oxide layer 240 are formed by processes, such as deposition process, lithography process and etching process. Materials of the third spacer 170 and the fourth spacer 270 may independently include oxides and/or nitrides, such as silicon dioxide, silicon nitride, silicon oxynitride or silicon carbonitride. Thereby, the fabrication of the semiconductor device 1 is completed. As shown in FIG. 10, the semiconductor device 1 includes a first device 12 and a second device 14.

Although not shown in the drawings, depending on actual needs, two source/drain regions may be formed at two sides of the first gate 150 in the first region 100 and two source/drain regions may be formed at two sides of the second gate 250 in the second region 200 of the substrate 10 by an ion implantation process. Furthermore, the non-metallic conductive materials of the first gate material layer 154 of the first gate 150 and/or the second gate material layer 254 of the second gate 250 may be replaced with a single-layer structure or a multi-layer structure including metallic conductive materials by a replacement metal gate (RMG) process. The aforementioned single-layer structure may only include a low-resistance metal layer, and a material of the low-resistance metal layer may include, for example, copper (Cu), aluminum (Al), tungsten (W), titanium aluminum alloy (TiAl), cobalt tungsten phosphide (CoWP) or a combination thereof. The aforementioned multi-layer structure may be formed by a low-resistance metal layer and a high-k dielectric layer and/or a barrier layer and/or a work function metal layer. The method for forming the source/drain regions and the replacement metal gate process are well known in the art and are omitted herein.

The aforementioned film layers, such as the first pad oxide layer 110, the second pad oxide layer 210, the insulating structure 300, the patterned mask 400, the first high-k material layer 152, the first gate material layer 154, the second high-k material layer 252, the second gate material layer 254, the first spacer 160, the second spacer 260, the third spacer 170 and the fourth spacer 270, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 10, which shows a schematic cross-sectional view of a semiconductor device 1 according to an embodiment of the present disclosure. The semiconductor device 1 includes the substrate 10, the first oxide layer 140 and the second oxide layer 240. The substrate 10 has the first region 100 and the second region 200. The first oxide layer 140 is disposed on the first region 100, wherein the first oxide layer 140 includes the first thermal oxide layer 142 and the first deposited oxide layer 144, and a portion of the first thermal oxide layer 142 is formed by a pad oxide layer (such as the first pad oxide layer 110 in FIG. 1). The second oxide layer 240 is disposed on the second region 200, wherein the second oxide layer 240 includes the second thermal oxide layer 242 and the second deposited oxide layer 244. The second thermal oxide layer 242 does not include a pad oxide layer (such as the second pad oxide layer 210 in FIG. 1).

The thickness t1 of the first thermal oxide layer 142 may be greater than the thickness t3 of the second thermal oxide layer 242. The thickness t2 of the first deposited oxide layer 144 may be equal to the thickness t4 of the second deposited oxide layer 244. Therefore, the thickness T1 of the first oxide layer 140 may be greater than the thickness T2 of the second oxide layer 240. In the first oxide layer 140, the thickness t1 of the first thermal oxide layer 142 may be greater than the thickness t2 of the first deposited oxide layer 144. In the second oxide layer 240, the thickness t3 of the second thermal oxide layer 242 may be greater than the thickness t4 of the second deposited oxide layer 244. For other details of the thicknesses t1, t2, t3, t4, T1 and T2, reference may be made to the above description and are not repeated herein.

According to an embodiment of the present disclosure, the thickness t1 of the first thermal oxide layer 142 may be 190 angstroms, and the thickness t3 of the second thermal oxide layer 242 may be 140 angstroms. The thickness t2 of the first deposited oxide layer 144 and the thickness t4 of the second deposited oxide layer 244 may be 70 angstroms. The thickness T1 of the first oxide layer 140 may be 260 angstroms, and the thickness T2 of the second oxide layer 240 may be 210 angstroms, but not limited thereto.

According to an embodiment of the present disclosure, the first pad oxide layer 110, the first thermal oxide layer 142 and the second thermal oxide layer 242 may include the same material, such as silicon dioxide.

The semiconductor device 1 may further include a first well region 120 and a second well region 220. The first well region 120 is in the first region 100 of the substrate 10, and the second well region 220 is in the second region 200 of the substrate 10. The semiconductor device 1 may further include two first light doped drains 130 and two second light doped drains 230. The two first light doped drains 130 are separated from each other and located at two opposite sides of the first well region 120. The two second light doped drains 230 are separated from each other and located at two opposite sides of the second well region 220.

The semiconductor device 1 may further include a first gate 150 and a second gate 250. The first gate 150 is disposed on the first oxide layer 140, and the second gate 250 is disposed on the second oxide layer 240. The first gate 150 includes a first high-k material layer 152 and a first gate material layer 154, and the first gate material layer 154 is disposed on the first high-k material layer 152. The second gate 250 includes a second high-k material layer 252 and a second gate material layer 254, and the second gate material layer 254 is disposed on the second high-k material layer 252. The materials of the first high-k material layer 152 and the second high-k material layer 252 may include oxides, nitrides or oxynitrides. The materials of the first gate material layer 154 and the second gate material layer 254 may include non-metallic conductive materials or a single-layer structure or a multi-layer structure including metallic conductive materials. For other details of the first gate 150 and the second gate 250, reference may be made to the above description and are not repeated herein.

The semiconductor device 1 may further include a first spacer 160 and a second spacer 260. The first spacer 160 surrounds the first gate 150 and is disposed on the first oxide layer 140. The second spacer 260 surrounds the second gate 250 and is disposed on the second oxide layer 240. The outer side surface 160b of the first spacer 160 is aligned with the side surface 140b of the first oxide layer 140, and the outer side surface 260b of the second spacer 260 is aligned with the side surface 240b of the second oxide layer 240. The semiconductor device 1 may further include a third spacer 170 and a fourth spacer 270. The third spacer 170 surrounds the first spacer 160 and the first oxide layer 140, and the third spacer 170 directly contacts the top surface 100b of the substrate 10 in the first region 100. The fourth spacer 270 surrounds the second spacer 260 and the second oxide layer 240, and the fourth spacer 270 directly contacts the top surface 200b of the substrate 10 in the second region 200.

More specifically, the semiconductor device 1 includes the first device 12 and the second device 14 disposed in the first region 100 and the second region 200, respectively. The first device 12 includes the substrate 10, the first well region 120, the two first light doped drains 130, the first oxide layer 140, the first gate 150, the first spacer 160 and the third spacer 170. The second device 14 includes the substrate 10, the second well region 220, the two second light doped drains 230, the second oxide layer 240, the second gate 250, the second spacer 260 and the fourth spacer 270. With the thickness T1 of the first oxide layer 140 being greater than the thickness T2 of the second oxide layer 240, the first device 12 and the second device 14 can sustain different operation voltages. Herein, the operation voltage that the first device 12 can sustain is greater than the operation voltage that the second device 14 can sustain, which is exemplary. According to an embodiment of the present disclosure, the operation voltages of the first device 12 and the second device 14 may be 10 V and 8 V, respectively. That is, the first device 12 and the second device 14 are medium voltage devices with different operation voltages, but not limited thereto. The operation voltages that the first device 12 and the second device can sustain may be changed by adjusting the thicknesses T1 and T2.

In a conventional semiconductor device, in order to fabricate the oxide layers of the first region and the second region with different thicknesses, one of the methods is to form oxide layers with the same thickness in the first region and the second region by a thermal oxidation process, and then a portion of the oxide layer in the second region is removed by processes, such as a lithography process and an etching process, cooperated with a patterned mask, so that the thickness of the oxide layer in the second region is less than the thickness of the oxide layer in the first region. However, when the thickness required by the oxide layer in the first region is thicker, forming the oxide layer by the thermal oxidation process alone may cause other problems due to excessively long heating time. Another one of the methods is to form oxide layers with the same thickness in the first region and the second region by an atomic layer deposition process, and then a portion of the oxide layer in the second region is removed by processes, such as a lithography process and an etching process, cooperated with a patterned mask, so that the thickness of the oxide layer in the second region is less than the thickness of the oxide layer in the first region. However, the cost of the atomic layer deposition process is relatively high. Forming the oxide layer by the atomic layer deposition process alone will significantly increase the production cost.

Compared with the prior art, in the method for fabricating the semiconductor device according to the present disclosure, by reserving the first pad oxide layer in the first region and cooperating with the thermal oxidation process and the atomic layer deposition process, the first pad oxide layer forms a portion of the first thermal oxide layer, so that the first oxide layer of the first region and the second oxide layer of the second region have different thicknesses. Accordingly, the first region and the second region can dispose devices with different operation voltages. On one hand, the problems caused by excessively long heating time when using the thermal oxidation process alone or the excessively high production costs when using the atomic layer deposition process alone can be avoided. On the other hand, in the present disclosure, it does not need to remove a portion of the second oxide layer to make the thickness of the second oxide layer less than the thickness of the first oxide layer by processes, such as a lithography process and an etching process, cooperated with a patterned mask. Therefore, it is beneficial to simplify the process and reduce the production costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate having a first region and a second region;
a first oxide layer disposed on the first region, wherein the first oxide layer comprises a first thermal oxide layer and a first deposited oxide layer, and a portion of the first thermal oxide layer is formed by a pad oxide layer; and
a second oxide layer disposed on the second region, wherein the second oxide layer comprises a second thermal oxide layer and a second deposited oxide layer.

2. The semiconductor device of claim 1, wherein the pad oxide layer, the first thermal oxide layer and the second thermal oxide layer comprise a same material.

3. The semiconductor device of claim 1, further comprising:
a first gate disposed on the first oxide layer; and
a second gate disposed on the second oxide layer.

4. The semiconductor device of claim 3, further comprising:
a first spacer surrounding the first gate and disposed on the first oxide layer; and
a second spacer surrounding the second gate and disposed on the second oxide layer.

5. The semiconductor device of claim 4, wherein an outer side surface of the first spacer is aligned with a side surface of the first oxide layer, and an outer side surface of the second spacer is aligned with a side surface of the second oxide layer.

6. The semiconductor device of claim 1, wherein a thickness of the first deposited oxide layer is equal to a thickness of the second deposited oxide layer.

7. The semiconductor device of claim 1, wherein a thickness of the first thermal oxide layer is greater than a thickness of the second thermal oxide layer.

8. The semiconductor device of claim 1, wherein a thickness of the first oxide layer is greater than a thickness of the second oxide layer.

9. The semiconductor device of claim 1, wherein in the first oxide layer, a thickness of the first thermal oxide layer is greater than a thickness of the first deposited oxide layer.

10. The semiconductor device of claim 1, wherein in the second oxide layer, a thickness of the second thermal oxide layer is greater than a thickness of the second deposited oxide layer.

11. A method for fabricating a semiconductor device, comprising:
providing a substrate having a first region and a second region;
forming a first pad oxide layer on the first region;
performing a thermal oxidation process to respectively form a first thermal oxide layer and a second thermal oxide layer on the first region and the second region, wherein a portion of the first thermal oxide layer is formed by the first pad oxide layer; and
performing a deposition process to form a first deposited oxide layer on the first thermal oxide layer in the first region and a second deposited oxide layer on the second thermal oxide layer in the second region.

12. The method of claim 11, further comprising:
forming a second pad oxide layer on the second region;
performing an ion implantation process; and
removing the second pad oxide layer.

13. The method of claim 11, wherein the first region comprises a first oxide layer, the second region comprises a second oxide layer, the first oxide layer comprises the first thermal oxide layer and the first deposited oxide layer, the second oxide layer comprises the second thermal oxide layer and the second deposited oxide layer, the method further comprises:
forming a first gate on the first oxide layer; and
forming a second gate on the second oxide layer.

14. The method of claim 13, further comprising:
forming a first spacer surrounding the first gate and disposed on the first oxide layer; and
forming a second spacer surrounding the second gate and disposed on the second oxide layer.

15. The method of claim 14, further comprising:
removing a portion of the first oxide layer and a portion of the second oxide layer, so that an outer side surface of the first spacer is aligned with a side surface of the first oxide layer, and an outer side surface of the second spacer is aligned with a side surface of the second oxide layer.

16. The method of claim 11, wherein a thickness of the first deposited oxide layer is equal to a thickness of the second deposited oxide layer.

17. The method of claim 11, wherein a thickness of the first thermal oxide layer is greater than a thickness of the second thermal oxide layer.

18. The method of claim 11, wherein a sum of a thickness of the first deposited oxide layer and a thickness of the first thermal oxide layer is greater than a sum of a thickness of the second deposited oxide layer and a thickness of the second thermal oxide layer.

19. The method of claim 11, wherein a thickness of the first thermal oxide layer is greater than a thickness of the first deposited oxide layer.

20. The method of claim 11, wherein a thickness of the second thermal oxide layer is greater than a thickness of the second deposited oxide layer.
